(19) United States
(12) Patent Application Publication
(10) Pub. No.: US 2013/0023112 A1
(43) Pub. Date: Jan. 24, 2013

(54) METHODS FOR POST DOPANT IMPLANT PURGE TREATMENT

(71) Applicant: Kartik SANTHANAM, Malta, NY (US)

(72) Inventor: Kartik SANTHANAM, Malta, NY (US)

(73) Assignee: APPLIED MATERIALS, INC., Santa Clara, CA (US)

(21) Appl. No.: 13/284,550

(22) Filed: Oct. 28, 2011

Related U.S. Application Data
(60) Provisional application No. 61/510,844, filed on Jul. 22, 2011.

(51) Int. Cl. H01L 21/22

(52) U.S. Cl. 438/513; 257/E21.135

(57) ABSTRACT

Methods for processing substrates are provided herein. In some embodiments, a method of processing a substrate may include implanting a substrate with a dopant in a first vacuum chamber; transferring the substrate to a second vacuum chamber at a first pressure below atmospheric; providing an inert gas to the second vacuum chamber to raise the pressure to a second pressure; pumping down the second vacuum chamber to a third pressure below the second pressure; and providing the inert gas to the second vacuum chamber to raise the pressure to a fourth pressure above the third pressure.

### CROSS-REFERENCE TO RELATED APPLICATIONS

This application claims benefit of U.S. provisional patent application Ser. No. 61/510,844, filed Jul. 22, 2011, which is herein incorporated by reference.

### FIELD

Embodiments of the present invention generally relate to semiconductor manufacturing.

### BACKGROUND

Fluorine-based precursors are often used in the semiconductor industry as the precursors in plasma doping processes. However, the inventor has observed that plasma doping with a fluorine based precursor may result in the continuing adsorption of fluorine into the surface of a semiconductor wafer during and after the implant process. As a result of such continued adsorption, the surface of the semiconductor wafer may develop a haze, which may result in semiconductor wafers being rejected from the production lot and/or undesirably incurring excess processing time to allow the haze to dissipate.

Accordingly, the inventor has provided improved methods of processing substrates.

### SUMMARY

Methods for processing substrates are provided herein. In some embodiments, a method of processing a substrate may include implanting a substrate with a dopant in a first vacuum chamber; transferring the substrate to a second vacuum chamber at a first pressure below atmospheric; providing an inert gas to the second vacuum chamber to raise the pressure to a second pressure; pumping down the second vacuum chamber to a third pressure below the second pressure; and providing the inert gas to the second vacuum chamber to raise the pressure to a fourth pressure above the third pressure.

In some embodiments, the inventive methods may be embodied on a computer readable medium as instructions that, when executed, cause a substrate processing system to perform any of the methods as described herein.

Other and further embodiments of the present invention are described below.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a flow chart for a method of processing a substrate in accordance with some embodiments of the present invention.

FIG. 2 depicts a cluster tool suitable for performing portions of the present invention in accordance with some embodiments of the present invention.

To facilitate understanding, identical reference numerals have been used, where possible, to designate identical elements that are common to the figures. The above drawings are not to scale and may be simplified for illustrative purposes.

### DETAILED DESCRIPTION

Embodiments of the present invention provide improved methods for processing substrates. Embodiments of the present invention may advantageously reduce the hazing effect caused by plasma doping processes. Embodiments of the inventive method further advantageously may have a minimal effect on production throughput. Exemplary, but non-limiting, examples of target areas for the improved process methods may include polydoping and conformal doping applications, fabrication of ultra shallow junctions (USJ), source drain regions, and flash memory, and other applications.

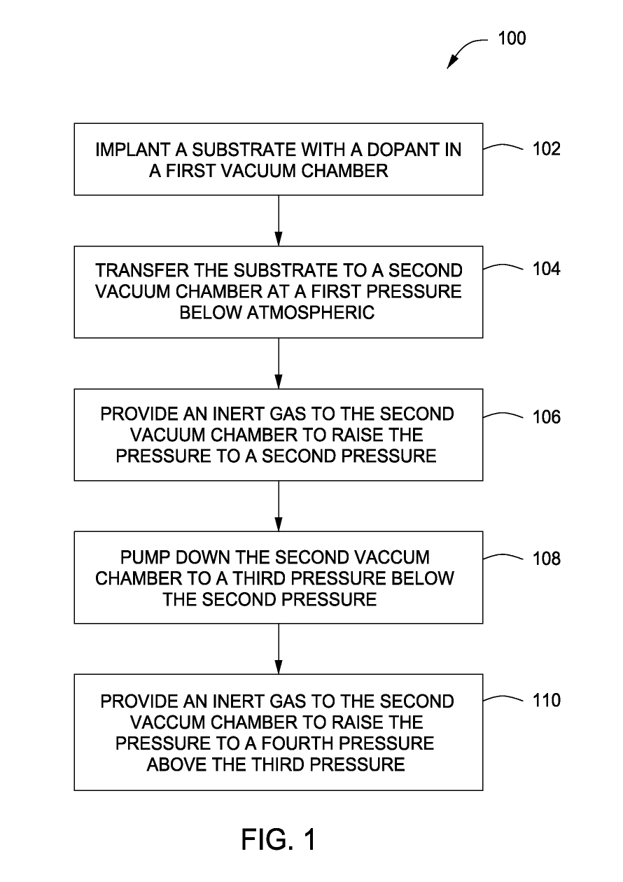

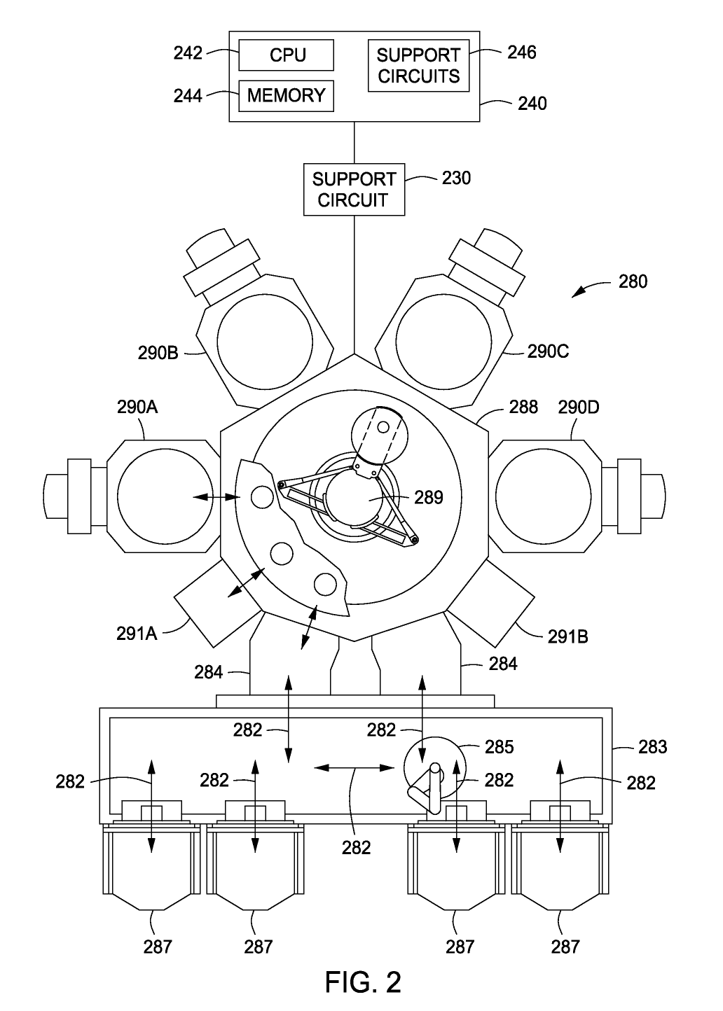

FIG. 1 depicts a method 100 for processing a substrate in accordance with some embodiments of the present invention. FIG. 2 depicts a cluster tool suitable for performing portions of the present invention in accordance with some embodiments of the present invention.

The method 100 generally begins at 102, where a substrate is implanted with a dopant in a first vacuum chamber. The dopant region may be formed by implanting one or more dopants into the substrate in an implantation process, such as a plasma assisted implantation process. Alternatively or in combination, the doping process may also be performed by depositing a dopant precursor on a surface of the substrate. Either process may be performed in any suitable doping chamber, such as a plasma-assisted doping chamber. Examples of suitable doping chambers include a plasma immersion ion implantation process chambers, such as the CONFORMA™ process chamber, available from Applied Materials, Inc., of Santa Clara, Calif. Other suitable process chambers may also be used, including process chambers from other manufacturers.

The substrate may comprise any suitable material used in the fabrication of semiconductor devices. For example, in some embodiments, the substrate may comprise a semiconducting material and/or combinations of semiconducting materials and non-semiconductive materials for forming semiconductor structures and/or devices. For example, the substrate may comprise one or more silicon-containing materials such as crystalline silicon (e.g., Si<100> or Si<111>), silicon oxide, strained silicon, polysilicon, silicon wafers, glass, sapphire, or the like. The substrate may further have any desired geometry, such as a 200 or 300 mm wafer, square or rectangular panels, or the like. In some embodiments, the substrate may be a semiconductor wafer (e.g., a 200 mm, 300 mm, or the like silicon wafer).

When doping the substrate, the entire surface of the substrate may be doped or if select regions of the substrate are to be doped, a patterned mask layer, such as a patterned photoresist layer, may be deposited atop the substrate to protect regions of the substrate that are not to be doped. For example, in some embodiments, a masking layer, such as a layer of photoresist, may be provided and patterned such that the dopant region is formed only on portions of the substrate.

The one or more dopants to be implanted may comprise any suitable element or elements typically used in semiconductor doping processes. In some embodiments, the dopant may be provided by a dopant precursor that comprises fluorine, such as, but not limited to, boron trifluoride (BF₃), phosphorus trifluoride (PF₃), carbon tetrafluoride (CF₄), di-arsenic fluoride (As₂F₅), silicon tetrafluoride (SiF₄), or the like. In some embodiments, the dopant may be provided by a dopant precursor that comprises a hydride, such as, but not limited to, diborane (B₂H₆), phosphine (PH₃), arsine (AsH₃), methane (CH₄), or the like. In some embodiments, the dose of the dopant ranges from 1E15 to 1E17 atoms/cm³.

Next, at 104, the substrate is transferred to a second vacuum chamber at a first pressure below atmospheric (760 Torr). In some embodiments the second vacuum chamber is a load lock chamber. In some embodiments the second vacuum chamber and the first vacuum chamber are each coupled to a common central chamber as part of a cluster tool suitable for performing portions of the present invention as depicted in FIG. 2 and further described below.

Next, at 106, an inert gas is provided to the second vacuum chamber to raise the pressure in the second vacuum chamber to a second pressure greater than the first pressure. In some embodiments, the second pressure may be atmospheric pressure. In some embodiments, the second pressure may be less than atmospheric. In some embodiments, the second pressure is between about 10 mTorr to about atmospheric pressure. In some embodiments, the inert gas is at least one of nitrogen or argon.

Next, at 108, the pressure in the second vacuum chamber is reduced to a third pressure below the second pressure. In some embodiments, the third pressure is substantially equal to the first pressure. In some embodiments, the third pressure is greater than the first pressure. In some embodiments, the third pressure is between about 2 mTorr to about 100 mTorr.

Next, at 110, an inert gas is provided to the second vacuum chamber to raise the pressure in the second vacuum chamber to a fourth pressure greater than the third pressure. In some embodiments, the fourth pressure may be atmospheric pressure. In some embodiments, the fourth pressure may be less than atmospheric. In some embodiments, the fourth pressure is substantially equal to the second pressure. In some embodiments, the fourth pressure is between about 10 mTorr to about atmospheric pressure. In some embodiments, the inert gas is at least one of nitrogen or argon. The inert gas may be the same or different than the inert gas provided at 106.

Upon completion of 110, the substrate may be moved as desired to another location for further processing. Optionally, the pressure may be reduced and raise in another cycle (e.g., reduced to a fifth pressure, then raised to a sixth pressure), however, the inventor has observed that this is often not necessary and is a tradeoff between particle and haze performance and process throughput. The inventor has observed that the above post-implant purge cycle advantageously removes or reduces the hazing effect believed to be a result of fluorine adsorption onto the surface of the substrate when performing implant process with fluorine based precursors. Thus, the above method advantageously improves process yield and throughput by reducing or eliminating the haze effect. The inventor has also observed that the above post-implant purge cycle advantageously reduces dangling atoms caused by hydrogen interaction with the substrate when the dopant precursor comprises a hydride.

FIG. 2 depicts a substrate processing system, or cluster tool, suitable for performing portions of the present invention. Generally, the cluster tool is a modular system comprising multiple chambers which perform various functions including substrate center-finding and orientation, capping, annealing, deposition and/or etching. In accordance with the embodiments of the present invention, the cluster tool may include a plasma doping chamber, and a load-lock chamber configured to perform the inventive steps described in the method 100 of the present invention. The multiple process chambers of the cluster tool are mounted to a central transfer chamber which houses a robot adapted to shuttle substrates between the chambers. The transfer chamber is typically maintained at a vacuum condition and provides an intermediate stage for shuttling substrates from one chamber to another and/or to a load lock chamber positioned at a front end of the cluster tool. The details of one such staged-vacuum substrate processing system is disclosed in U.S. Pat. No. 5,186,718, entitled “Staged-Vacuum Substrate Processing System and Method,” Tepman et al., issued on Feb. 16, 1993. However, the exact arrangement and combination of chambers may be altered for purposes of performing specific steps of a fabrication process, which includes the present methods for limiting hazing effects on a substrate.

By way of illustration, a particular cluster tool 280 is shown in a plan view in FIG. 4. The cluster tool 280 generally comprises a plurality of chambers and robots and is preferably equipped with a microprocessor controller 240 programmed to carry out the various processing methods performed in the cluster tool 280. A front-end environment 283 is shown positioned in selective communication with a pair of load lock chambers 284. A pod loader 285 disposed in the front-end environment 283 is capable of linear and rotational movement (arrows 282) to shuttle cassettes of substrates between the load locks 284 and a plurality of pods 287 which are mounted on the front-end environment 283. The load locks 284 provide a first vacuum interface between the front-end environment 283 and a transfer chamber 288. Two load locks 284 are provided to increase throughput by alternatively communicating with the transfer chamber 288 and the front-end environment 283. Thus, while one load lock 284 communicates with the transfer chamber 288, a second load lock 284 communicates with the front-end environment 283. A robot 289 is centrally disposed in the transfer chamber 288 to transfer substrates from the load locks 284 to one of the various processing chambers 290 and service chambers 291. The processing chambers 290 may perform any number of processes such as physical vapor deposition, chemical vapor deposition, and etching while the service chambers 291 are adapted for degassing, orientation, cooldown and the like.

In some embodiments, at least one of the processing chambers 290 is configured as a plasma doping process chamber. In some embodiments, the plasma doping chamber may be used to form the dopant region on the substrate.

The controller 240 generally comprises a central processing unit (CPU) 242, a memory 244, and support circuits 246 and is coupled to and controls the cluster tool 280 and support systems 230, directly (as shown in FIG. 4) or, alternatively, via computers (or controllers) associated with the process chamber and/or the support systems.

The controller 240 may contain a computer-readable medium having instruction stored thereon for performing the methods described above in accordance with the embodiments of the invention. When the computer-readable medium is read by the controller, the controller 240 issues instructions to perform the inventive methods to the process chambers 290 and/or load lock chambers 284 directly, or alternatively, via computers (or controllers) associated with the process chambers 290, load lock chambers 284, and/or their support systems. Alternatively, the computer-readable medium for performing the methods of the invention may be contained on one or more of the controllers associated with the process chambers 290 and/or load lock chambers 284.

Thus, methods for processing a substrate are provided herein. While the foregoing is directed to embodiments of the present invention, other and further embodiments of the invention may be devised without departing from the basic scope thereof.

1. A method of processing a substrate, comprising:
implanting a substrate with a dopant in a first vacuum chamber;
transferring the substrate to a second vacuum chamber at a first pressure below atmospheric;
providing an inert gas to the second vacuum chamber to raise the pressure to a second pressure;
pumping down the second vacuum chamber to a third pressure below the second pressure; and
providing the inert gas to the second vacuum chamber to raise the pressure to a fourth pressure above the third pressure.

2. The method of claim 1, wherein the first pressure is substantially equal to the third pressure.

3. The method of claim 1 wherein the second pressure is substantially equal to the fourth pressure.

4. The method of claim 1, wherein the fourth pressure is substantially equal to atmospheric pressure.

5. The method of claim 1, wherein the second pressure is less than atmospheric pressure and wherein the fourth pressure is substantially equal to atmospheric pressure.

6. The method of claim 1, wherein the second pressure is about 10 mTorr to about atmospheric pressure.

7. The method of claim 1, wherein the third pressure is about 2 mTorr to about 100 mTorr.

8. The method of claim 1, wherein the fourth pressure is about 10 mTorr to about atmospheric pressure.

9. The method of claim 1, wherein the second pressure is about 10 mTorr to about atmospheric pressure, wherein the third pressure is about 2 mTorr to about 100 mTorr, and wherein the fourth pressure is about 10 mTorr to about atmospheric pressure.

10. The method of claim 1, wherein the second vacuum chamber is a loadlock chamber

11. The method of claim 10, wherein the loadlock chamber and the first vacuum chamber are each coupled to a common central transfer chamber having a substrate transfer robot disposed therein to transfer the substrate between the first vacuum chamber and the loadlock chamber.

12. The method of claim 1, wherein the dopant is provided by a dopant precursor comprising fluorine.

13. The method of claim 1, wherein the dopant precursor comprises at least one of boron trifluoride (BF₃), phosphorus trifluoride (PF₃), carbon tetrafluoride (CF₄), di-arsenic fluoride (As₂F₅), or silicon tetrafluoride (SiF₄).

14. The method of claim 1, wherein the dopant is provided by a dopant precursor comprising a hydride.

15. The method of claim 14, wherein the dopant precursor comprises at least one of diborane (B₂H₆), phosphine (PH₃), arsine (AsH₃), or methane (CH₄)

16. The method of claim 1, wherein the dose of the dopant ranges from 1E15 to 1E17 atoms/cm².

17. The method of claim 1, wherein the inert gas comprises at least one of nitrogen or argon.

18. A computer readable medium having instructions stored thereon that, when executed, cause a substrate processing system to perform a method, the method comprising:
implanting a substrate with a dopant in a first vacuum chamber;
transferring the substrate to a second vacuum chamber at a first pressure below atmospheric;
providing an inert gas to the second vacuum chamber to raise the pressure to a second pressure;
pumping down the second vacuum chamber to a third pressure below the second pressure; and
providing the inert gas to the second vacuum chamber to raise the pressure to a fourth pressure above the third pressure.

19. The computer readable medium of claim 18, wherein the first pressure is substantially equal to the third pressure, and wherein the fourth pressure is about atmospheric pressure.

20. The computer readable medium of claim 18, wherein the second pressure is about 10 mTorr to about atmospheric pressure, wherein the third pressure is about 2 mTorr to about 100 mTorr, and wherein the fourth pressure is about atmospheric pressure.
